(19) United States
(12) Patent Application Publication
(10) Pub. No.: US 2023/0315133 A1
(43) Pub. Date: Oct. 5, 2023

(54) ACCUMULATOR FOR A COOLANT DISTRIBUTION UNIT

(71) Applicant: HEWLETT PACKARD ENTERPRISE DEVELOPMENT LP, Houston, TX (US)

(72) Inventors: Michael Scott, Chippewa Falls, WI (US); Harvey J. Lunsman, Chippewa Falls, WI (US)

(21) Appl. No.: 17/708,270

(22) Filed: Mar. 30, 2022

(51) Int. Cl. G05D 16/10; H05K 7/20

(52) U.S. Cl. CPC G05D 16/10; H05K 7/20781

(57) ABSTRACT

Example implementations relate to an accumulator for regulating variations in operating pressure of a cool fluid in a closed fluid loop of a coolant distribution unit (CDU). The accumulator includes a cylinder having an internal volume defined between an inlet and outlet, and a hollow piston slidably connected to the cylinder through one of the inlet or outlet to split the internal volume into a first volume portion filled with the cool fluid and a second volume portion filled with a compressible matter that is maintained at the operating pressure by the cool fluid filled in the first volume portion via the hollow piston. The first volume portion is fluidically connected to the closed fluid loop functioning at the operating pressure via the hollow piston and other one of the inlet or the outlet to direct a flow of the cool fluid into the closed fluid loop via the accumulator.

### CROSS REFERENCE

This application is related to a co-pending U.S. application titled “Cool fluid reservoir for a coolant distribution unit” filed on “Mar. 30, 2022” (U.S. application Ser. No. 17/708,240), which has Invention Reference Number “710230823US01”, and is assigned to Hewlett Packard Enterprise Development LP.

### BACKGROUND

Data center environments may include electronic systems, such as server systems, storage systems, wireless access points, network switches, routers, or the like. Each electronic system may include electronic components that operate optimally within a temperature range. During the operation of such electronic systems, the electronic components may generate waste-heat. Accordingly, each electronic system may have to be cooled to maintain the electronic components within the temperature range. For example, a coolant distribution unit (CDU) of the data center environment may circulate a cool fluid into a closed fluid loop to dissipate the waste-heat generated from the electronic components of each electronic system and maintain the electronic components within the temperature range. However, the cool fluid directed in the closed fluid loop of the CDU may undergo pressure variations due to pressure spikes and/or thermal expansion and contraction of the cool fluid. The pressure spikes and/or the thermal expansion and contraction may occur due to varied rates of power consumption by the electronic systems for executing one or more workloads of the customer(s). Accordingly, an accumulator connected to the closed fluid loop may provide pressure relief in response to such pressure spikes and/or thermal expansion and contraction of the cool fluid to return the cool fluid to an operating pressure in the closed fluid loop.

### BRIEF DESCRIPTION OF THE DRAWINGS

Various examples will be described below with reference to the following figures.

FIG. 1A illustrates a block diagram of a chassis having a coolant distribution unit and a plurality of electronic systems according to an example implementation of the present disclosure.

FIG. 1B illustrates a cross-sectional view of an accumulator of the coolant distribution unit of FIG. 1A, in a normal condition according to the example implementation of the present disclosure.

FIG. 10 illustrates a cross-sectional view of the accumulator of FIGS. 1A-1B, in a contracted condition according to the example implementation of the present disclosure.

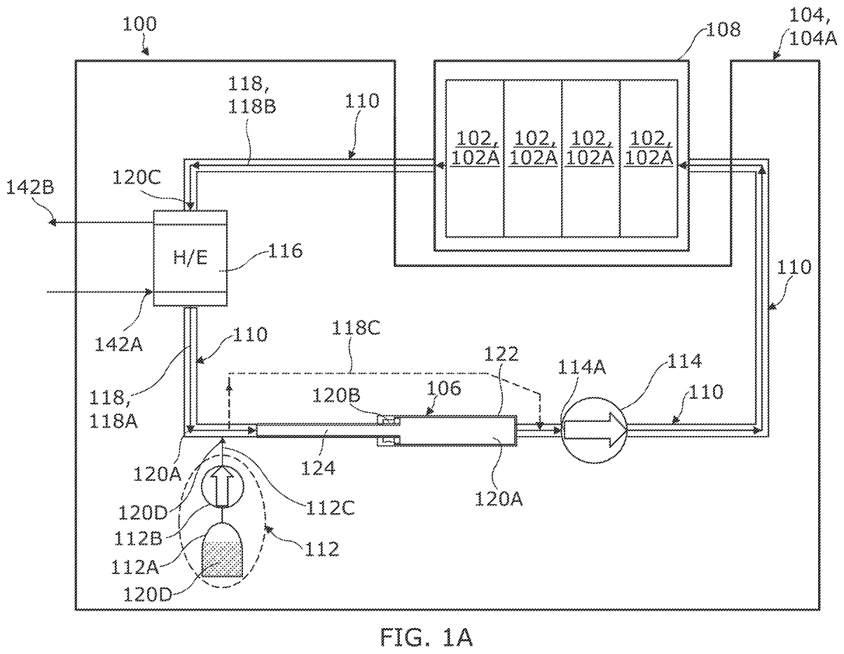

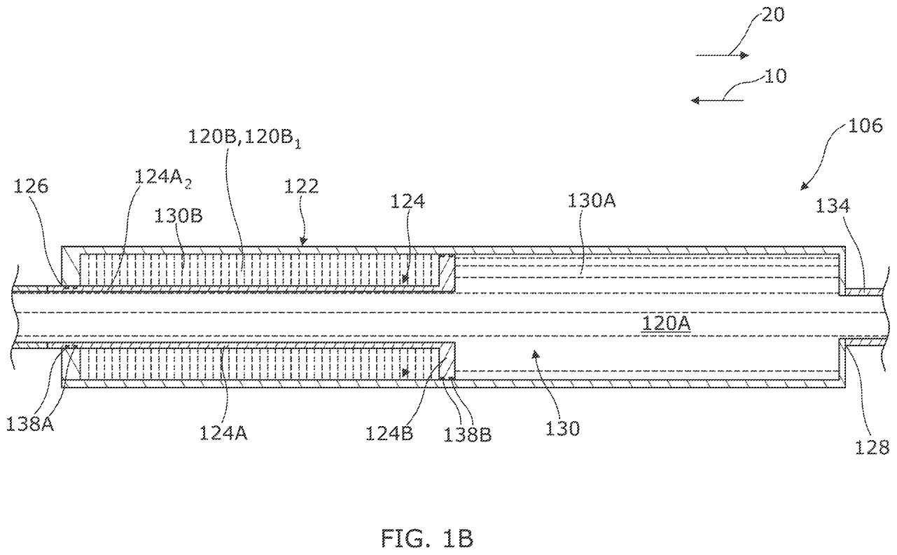

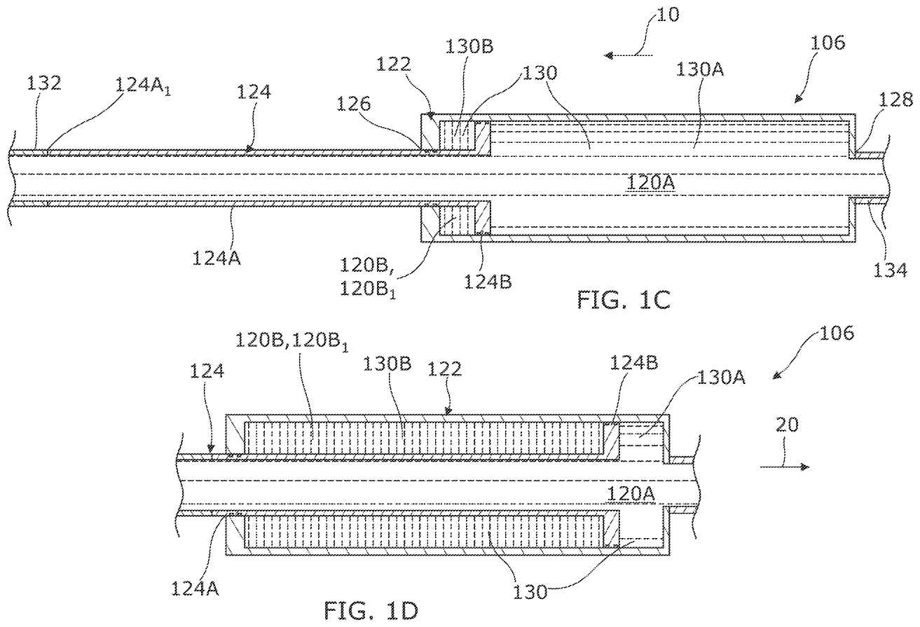

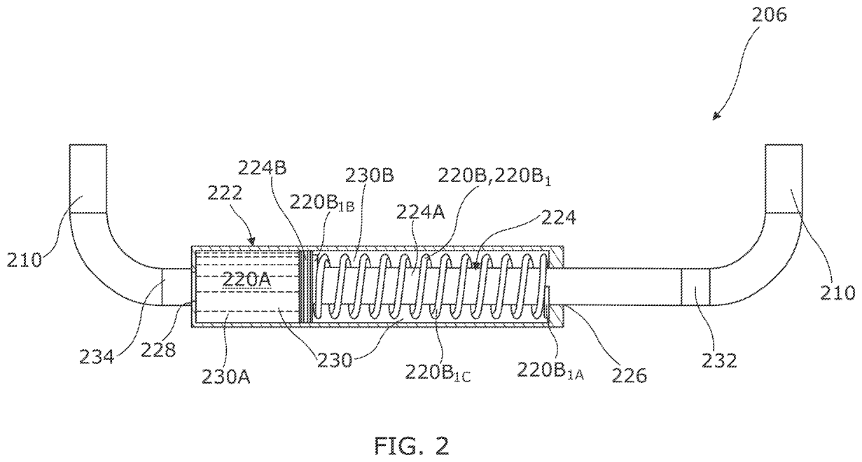

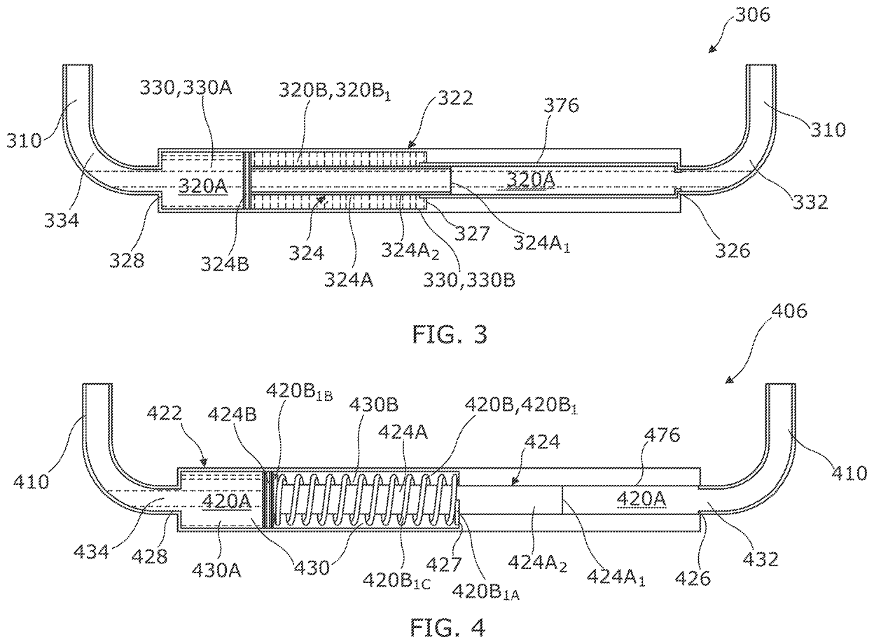

FIG. 1D illustrates a cross-sectional view of the accumulator of FIGS. 1A-10, in an expanded condition according to the example implementation of the present disclosure.

FIG. 2 illustrates a cross-sectional view of an accumulator according to another example implementation of the present disclosure.

FIG. 3 illustrates a cross-sectional view of an accumulator according to yet another example implementation of the present disclosure.

FIG. 4 illustrates a cross-sectional view of an accumulator according to yet another example implementation of the present disclosure.

FIG. 5A illustrates a cross-sectional view of an accumulator in a contracted condition according to yet another example implementation of the present disclosure.

FIG. 5B illustrates a cross-sectional view of the accumulator of FIG. 5A in an expanded condition according to the other example implementation of the present disclosure.

FIG. 6 illustrates a flowchart depicting a method of operating an accumulator to regulate variations in operating pressure of a cool fluid in a closed fluid loop of a coolant distribution unit according to an example implementation of the present disclosure.

### DETAILED DESCRIPTION

The following detailed description refers to the accompanying drawings. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the disclosed examples may be defined by the appended claims.

The terminology used herein is for the purpose of describing examples only and is not intended to be limiting. As used herein, the singular forms “a,” “an,” and “the” are intended to include the plural forms as well, unless the context indicates otherwise. The term “plurality,” as used herein, is defined as two, or more than two. The term “another,” as used herein, is defined as at least a second or more. The term “coupled,” as used herein, is defined as connected, whether directly without any intervening elements or indirectly with at least one intervening element, unless otherwise indicated. Two elements may be coupled mechanically, electrically, or communicatively linked through a communication channel, pathway, network, or system. The term “and/or” as used herein refers to and encompasses any and all possible combinations of one or more of the associated listed items. It will also be understood that, although the terms first, second, third, etc. may be used herein to describe various elements, these elements should not be limited by these terms, as these terms are only used to distinguish one element from another unless stated otherwise or the context indicates otherwise. As used herein, the term “includes” means includes but not limited to, the term “including” means including but not limited to. The term “based on” means based at least in part on.

For purposes of explanation, certain examples are described with reference to the components or elements illustrated in FIGS. 1-6. The functionality of the illustrated components or elements may overlap, however, and may be present in a fewer or greater number of elements or components. Further, all or part of the functionality of illustrated elements may co-exist or be distributed among several geographically dispersed locations. Moreover, the disclosed examples may be implemented in various environments and are not limited to the illustrated examples. Further, the sequence of operations performed for adding a cool fluid into a coolant distribution unit described in connection with FIG. 6, is an example and is not intended to be limiting. Additional or fewer operations or combinations of operations may be used or may vary without departing from the scope of the disclosed examples. Thus, the present disclosure merely sets forth possible examples of implementations, and many variations and modifications may be made to the described examples. Such modifications and variations are intended to be included within the scope of this disclosure and protected by the following claims.

A data center environment may include electronics systems for executing one or more customer workloads and a CDU for thermal management of the electronic systems. Examples of electronic systems may include, but are not limited to, server systems, storage systems, wireless access points, network switches, or the like. During the operation of the data center environment, the electronic systems executing workloads may generate waste heat. The CDU may circulate cool fluid to the electronic systems via a closed fluid loop to dissipate the waste-heat from the electronic systems. For example, the closed fluid loop may direct the cool fluid through cooling components, such as cold plates disposed in thermal contact with electronic components of each electronic system, to transfer the waste-heat from a respective electronic component to the cool fluid. Examples of the electronic components may include, but are not limited to, central processing units (CPUs), graphics processing units (GPUs), power supply units, memory chips, or other electronic elements, such as capacitors, inductors, resistors, or the like. However, the cool fluid directed in the closed fluid loop may undergo pressure (e.g., operating pressure) variations due to pressure spikes and/or thermal expansion and contraction of the cool fluid. Generally, such variations in the operating pressure may cause cavitation in circulation pumps, resulting in pump damage. Further, cavitation may also occur at certain pressure points in the plumbing, resulting in damage to the plumbing, thus leading to a premature CDU failure.

One solution to address such issues in the art may include using a pressure regulation device (e.g., an accumulator) in a CDU to regulate pressure (e.g., operating pressure) variations of a cool fluid in a closed fluid loop of the CDU. For example, the accumulator connected to the closed fluid loop may provide pressure relief in response to pressure spikes and/or thermal expansion and contraction of the cool fluid to regulate the pressure variations. Accordingly, the accumulator may assist the cool fluid to return to the operating pressure in the closed fluid loop. The accumulator may generally have a stored volume of working fluid (e.g., cool fluid) in its internal volume at the operating pressure. In such case, the accumulator, which is connected to the closed fluid loop, may inject a portion of the stored cool fluid into the closed fluid loop and/or extract the portion of the cool fluid from the closed fluid loop to regulate the pressure variations in the closed fluid loop. Since the cool fluid circulated in the closed fluid loop does not frequently undergo pressure variations, the stored cool fluid in the accumulator may remain stagnant for long periods. Chemicals in the stored cool fluid may degrade and/or may come out of (or release from) the stored cool fluid. Hence, the stored cool fluid may degrade such that it no longer maintains certain properties, such as corrosion and biological growth inhibition properties. Such properties are essential to minimize degradation of the closed fluid loop. As a result, when some portion of such stored cool fluid is injected into the closed fluid loop, it may inadvertently introduce bacteria and/or corrosive particles into the closed fluid loop, thereby contaminating the whole mixture of the cool fluid in the closed fluid loop. Thus, the electronic systems may be forced to undergo unavoidable shut down for replacement of contaminated cool fluid.

A technical solution to the aforementioned problems may include providing an accumulator having an internal volume filled with a cool fluid to be positioned in a fluid flow path defined by a closed fluid loop. The accumulator allows a continuous flow of the cool fluid into the closed fluid loop via the accumulator's internal volume. Since the cool fluid filled in the internal volume of the accumulator flows continuously, stagnation of the cool fluid may not occur there. Accordingly, the accumulator of the present disclosure may overcome one or more problems associated with the stagnation of the stored cool fluid in the existing accumulator. Further, the accumulator may get actuated (e.g., reciprocated) when an operating pressure of the cool fluid is increased and decreased in the closed fluid loop. This injects or extracts a portion of the cool fluid from the internal volume into the closed fluid loop to return pressure levels to the operating pressure. Accordingly, the accumulator may additionally regulate the pressure variations of the cool fluid in the closed fluid loop. This helps prevent fluid stagnation, thus diminishing circulation pump cavitation problems.

In some examples, the accumulator includes a cylinder having an internal volume defined between an inlet and an outlet, and a hollow piston slidably connected to the cylinder via one of the inlet or the outlet. In such examples, the hollow piston and other one of the inlet or the outlet are fluidically connected to the fluid flow path of the closed fluid loop to allow the continuous flow of the cool fluid through the accumulator. Thus, the accumulator may ensure that there is no stagnation of the cool fluid in its internal volume. Further, the hollow piston may be reciprocated inside the cylinder by a compressible matter, to inject a portion of the cool fluid filled in the internal volume of the cylinder into the closed fluid loop and extract the portion of the cool fluid from the closed fluid loop into the internal volume of the cylinder. Thus, the accumulator may ensure that the cool fluid injected into the closed fluid loop or extracted from the closed fluid loop has the same chemistry as the rest of the cool fluid in the closed fluid loop. Accordingly, the accumulator of the present disclosure may overcome the one or more problems related to stagnation of the cool fluid and simultaneously regulate the pressure variations of the cool fluid in the closed fluid loop in response to the pressure spikes and/or the thermal expansion and contraction of the cool fluid in the closed fluid loop.

Accordingly, the present disclosure describes example implementations of an accumulator for regulating variations in operating pressure of cool fluid in a closed fluid loop of a CDU. The accumulator includes a cylinder and a hollow piston. The cylinder has an internal volume defined between an inlet and an outlet. The hollow piston is slidably connected to the cylinder via one of the inlet or the outlet to split the internal volume into a first volume portion that is filled with the cool fluid and a second volume portion that is filled with a compressible matter. The compressible matter is maintained at the operating pressure by the cool fluid filled in the first volume portion via the hollow piston. The first volume portion is fluidically connected to the closed fluid loop functioning at the operating pressure via the hollow piston and other one of the inlet or the outlet to direct a flow of the cool fluid into the closed fluid loop via the accumulator. Further, the hollow piston of the accumulator reciprocates inside the cylinder upon i) expansion of the compressible matter to inject a portion of the cool fluid from the first volume portion into the closed fluid loop and ii) contraction of the compressible matter to extract the portion of the cool fluid from the closed fluid loop into the first volume portion to regulate variations in the operating pressure of the cool fluid at a pump-inlet of the circulation pump.

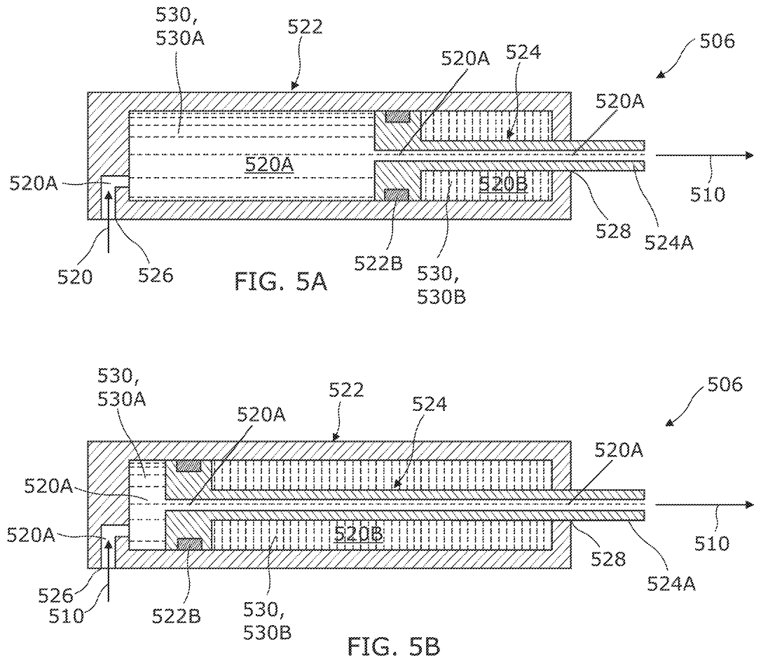

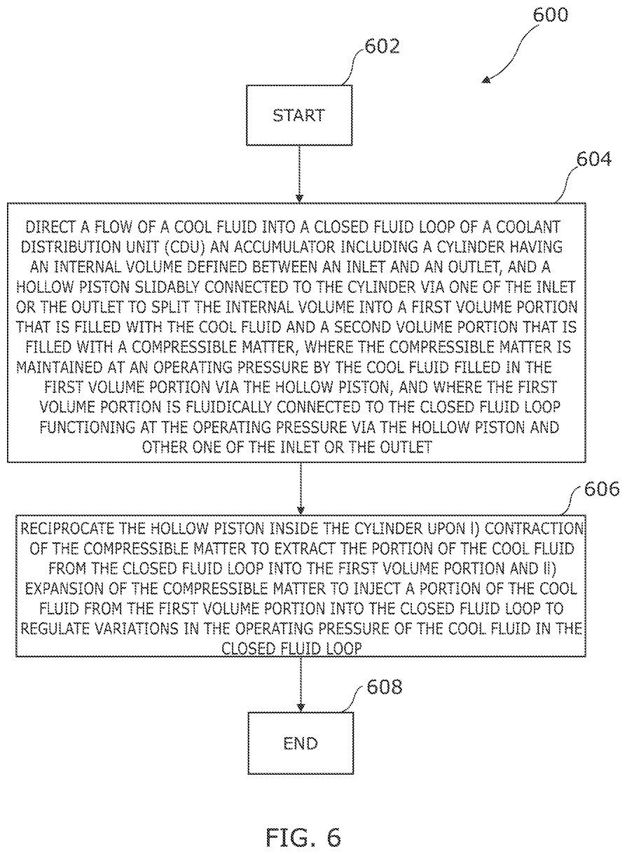

Turning to the Figures, FIG. 1A depicts a block diagram of a data center environment 100 having a plurality of electronic systems 102 and a thermal management system 104, for example, a CDU 104A. FIG. 1B depicts a cross-sectional view of an accumulator 106 of the CDU 104A of FIG. 1A, in a normal condition. FIG. 10 depicts a cross-sectional view of the accumulator 106 of FIGS. 1A-1B, in a contracted condition. FIG. 1D depicts a cross-sectional view of the accumulator 106 of FIGS. 1A-10, in an expanded condition. In the description hereinafter, FIGS. 1A-1D are described concurrently for ease of illustration.

Referring to FIG. 1A, the plurality of electronic systems 102 is disposed within an interior space of a chassis 108 (or an enclosure). The CDU 104A and the chassis 108 may be deployed in a rack or a cabinet (not shown) of the data center environment 100. In such examples, the CDU 104A deployed in the rack may be referred to as a “rack-level CDU” or a “cabinet-level CDU”. During the operation of the data center environment 100, the plurality of electronic systems 102 may execute one or more workloads of customer(s) and the CDU 104A may perform thermal management of the plurality of electronic systems 102 deployed in the chassis 108.

In some other examples, a rack may be configured to deploy one or more chassis, each having only the plurality of electronics systems 102 and another rack may be configured to deploy only a CDU. In such examples, the CDU deployed in the other rack may be referred as a “centralized CDU”. During the operation of such data center environment, the centralized CDU may be configured to perform the thermal management of the plurality of electronic systems 102 deployed in each of the one or more chassis deployed in the rack.

The plurality of electronic systems 102 may include server systems, storage systems, wireless access points, network switches, routers, or the like. In the example of FIG. 1A, each of the plurality of electronic systems 102 is a server system 102A. Each of the plurality of electronic systems 102 may include electronic components (not shown), such as central processing units (CPUs), power supply units, memory chips, or other electronic elements, such as capacitors, inductors, resistors, or the like. As discussed herein, the electronic components may generate a considerable amount of waste-heat, while operating to execute one or more workloads of customer(s). In such examples, the CDU 104A may be configured to dissipate the waste-heat from each of the plurality of electronic systems 102 to enable proper functioning of the electronic components and prevent damage to the electronic components due to the waste-heat.

In some examples, the CDU 104A includes an accumulator 106, a closed fluid loop 110, a cool fluid reservoir assembly 112, a circulation pump 114, a heat exchanger 116, and cooling components (not shown). It may be noted herein that the CDU 104A discussed in the example of FIG. 1A is the rack-level CDU or the cabinet-level CDU. In some other examples, the CDU 104A may be the centralized CDU, without deviating from the scope of the present disclosure.

The closed fluid loop 110 may include plumbing, which may be connected to each other at multiple intersections to define a fluid flow path 118. The fluid flow path 118 may direct a flow of a cool fluid 120 and a hot fluid 120C within the closed fluid loop 110 for thermal management of the plurality of electronic systems 102 deployed in the chassis 108. The fluid flow path 118 has a cool fluid flow path 118A and a hot fluid flow path 118B connected to each other to define the flow path of the closed fluid loop 110. The cool fluid flow path 118A extends from the heat exchanger 116 to the plurality of electronic systems 102 via the accumulator 106 and the circulation pump 114. In such examples, the cool fluid reservoir assembly 112 is disposed between the heat exchanger 116 and the accumulator 106, and connected to the cool fluid flow path 118A of the closed fluid loop 110 via a connector fluid flow path 112C. The hot fluid flow path 118B extends from the plurality of electronic systems 102 to the heat exchanger 116. In one or more examples, the cool fluid flow path 118A directs the flow of the cool fluid 120A from the heat exchanger 116 to the plurality of electronic systems 102, and the hot fluid flow path 118B directs the flow of the hot fluid 120C from the plurality of electronic systems 102 to the heat exchanger 116.

In the example of FIG. 1A, the accumulator 106 is disposed in the cool fluid flow path 118A. In some other examples, the accumulator 106 may be disposed in an auxiliary fluid flow path 118C defined by the closed fluid loop 110. The auxiliary fluid flow path 118C protrudes from the cool fluid flow path 118A, extends parallel to the cool fluid flow path 118A, and merges back to the cool fluid flow path 118A. However, the cool fluid flow path 118A extends directly from the heat exchanger 116 to the circulation pump 114. In some examples, the accumulator 106 disposed in the auxiliary fluid flow path 118C may avoid issues related to pressure drops at a pump-inlet 114A of the circulation pump 114. In one or more examples, the accumulator 106 regulates variation in the operating pressure of the cool fluid 120A in the closed fluid loop 110. For example, the accumulator 106 may provide pressure relief to the cool fluid 120A in the closed fluid loop 110 in response to variations in the operating pressure caused because of pressure spikes and/or thermal expansion and contraction of the cool fluid 120A in the closed fluid loop 110. The pressure spikes and/or the thermal expansion and contraction may occur due to the amount of waste-heat that the plurality of electronics systems 102 executing the one or more workloads generate due to varied power consumption rates. In such examples, the accumulator 106 ensures that positive pressure is maintained in the closed fluid loop 110, for example, at the pump-inlet 114A to allow the circulation pump 114 to pump the cool fluid 120A in the closed fluid loop 110 without any issues related to cavitation in the circulation pump 114 and in the plumbing of the CDU 104A.

Referring to FIG. 1B, the accumulator 106 includes a cylinder 122 and a hollow piston 124. Cylinder 122 includes an inlet 126, an outlet 128, and an internal volume 130 defined between the inlet 126 and the outlet 128. The hollow piston 124 includes a hollow-rod section 124A and a hollow-head section 124B extended from the hollow-rod section 124A. The hollow piston 124 is slidably connected to the cylinder 122 via the inlet 126 to split the internal volume 130 into a first volume portion 130A that is filled with the cool fluid 120A and a second volume portion 130B that is filled with a compressible matter 120B.

The accumulator 106 in the normal condition may have the compressible matter 120B maintained at an operating pressure by the cool fluid 120A via the hollow piston 124, as shown in FIG. 1B. In some examples, the compressible matter 120B may be at an ambient pressure when it is initially filled within (or disposed in) the second volume portion 130B. In such examples, the compressible matter 120B may occupy up to 90 percent of the internal volume 130 of the cylinder 122 at the ambient pressure. Later, the cool fluid 120A may be added in the first volume portion 130A with an end section 124A₁ (as shown in FIG. 10) of the hollow-rod section 124A been in a closed position, so as to compress the compressible matter 120B filled within the second volume portion 130B via the hollow piston 124, until the compressible matter 120B is compressed to the operating pressure. Thus, the accumulator 106 may attain the normal condition. In some examples, when the accumulator is in the normal condition, the compressible matter 120B may occupy up to 50 percent of the internal volume 130 of the cylinder 122 at the operating pressure. In some examples, the compressible matter 120B is held in the second volume portion 130B at a pressure in a range from about 10 per square inch (psi) to 150 psi.

The accumulator 106 in the normal condition is then connected to the cool fluid flow path 118A of the closed fluid loop 110. It may be noted herein that the cool fluid 120A directed in the closed fluid loop 110 is also maintained at the operating pressure, thus allowing the accumulator 106 in the normal condition to retain the compressible matter 120B at the operating pressure after connecting to the closed fluid loop 110. As used herein the term “operating pressure” may be a working pressure about which the CDU is designed to direct (or circulate) the cool fluid to the plurality of electronic systems via the closed fluid loop to dissipate waste-heat (e.g., a nominal amount of waste heat) from the plurality of electronic systems. As used herein the term “ambient pressure” may refer to atmospheric pressure. In one or more examples, the cool fluid 120A is one of a mixture of water and propylene glycol with additives, a dielectric fluid, water, or a 460-CCL100 fluid. In the example of FIGS. 1A-1D, the compressible matter 120B is a compressible fluid 120B₁, such as air. In some examples, the water and propylene glycol may be in a ratio from about 95:5 percent to about 50:50 percent. Further, the additives may include corrosion inhibitors and biocides.

The accumulator 106 further includes a pair of first sealing elements 138A and a pair of second sealing elements 138B. The pair of first sealing elements 138A may be coupled to the inlet 126 of the cylinder 122. In such examples, the pair of first sealing elements 138A may seal a first contact interface between the inlet 126 and an outer surface of the hollow-rod section 124A to prevent leakage of the compressible fluid 120B₁ from the second volume portion 130B to outside the accumulator 106. The pair of second sealing elements 138B may be coupled to the hollow-head section 124B. The pair of second sealing elements 138B may seal a second contact interface between an inner surface of the cylinder 122 and the hollow-head section 124B to prevent the leakage of the compressible fluid 120B₁ from the second volume portion 130B into the first volume portion 130A, and the cool fluid 120A from the first volume portion 130A into the second volume portion 130B.

Referring to FIGS. 1A-1B, the first volume portion 130A of the cylinder 122 is fluidically connected to the closed fluid loop 110 via the hollow piston 124 and the outlet 128 of the cylinder 122. For example, the end section 124A₁ (as shown in FIG. 10) of the hollow-rod section 124A (in an open position) is directly connected to the closed fluid loop 110 via a first hose 132, and the outlet 128 of the cylinder 122 is connected to the closed fluid loop 110 via a second hose 134 of the closed fluid loop 110. In some examples, the first hose 132 is a flexible hose and the second hose 134 is a rigid hose. During the operation of the accumulator 106, a portion 124A₂ (as shown in FIG. 1B) of the hollow-rod section 124A may slide lengthwise through the inlet 126 when the hollow piston 124 reciprocates inside the cylinder 122. Since the first hose 132 is a flexible hose, the portion 124A₂ of the hollow-rod section 124A may be allowed to slide lengthwise through the inlet 126 when the hollow-head section 124B reciprocates inside the cylinder 122.

Referring back to FIG. 1A, the cool fluid 120A may be directed from the heat exchanger 116 to the circulation pump 114 via the accumulator 106. In other words, the first volume portion 130A, which is fluidically connected to the closed fluid loop 110 via the hollow piston 124 and the outlet 128 may allow a continuous flow of the cool fluid 120A from the heat exchanger 116 to the circulation pump 114 via the accumulator 106. Accordingly, the accumulator 106 of the present disclosure may prevent stagnation of the cool fluid 120A within the accumulator 106, and thereby overcome one or more problems associated with the stagnation of the cool fluid 120A within the accumulator 106.

Further, when the accumulator 106 is in the normal condition, the compressible matter 120B may be maintained at the operating pressure to allow a flow of the cool fluid 120A at the operating pressure, to be directed to the plurality of electronic components 102 via the first volume portion 130A of the accumulator 106. However, when the accumulator 106 moves to the actuated condition (e.g., expanded or contracted conditions), the compressible matter 120B may be expanded and/or contracted to regulate variations in the operating pressure of the cool fluid 120A in the closed fluid loop 110. For example, the expansion and contraction of the compressible matter 120B may result in producing a reciprocating motion of the hollow piston 124 inside the cylinder 122. In some examples, the reciprocating motion may cause the hollow-head section 124B of the hollow piston 124 to reciprocate along a first direction 10 and a second direction 20 opposite to the first direction 10, inside the cylinder 122. For example, the hollow-head section 124B may slide along the first direction 10 upon contraction of the compressible matter 120B to extract a portion of the cool fluid 120A from the closed fluid loop 110 into the first volume portion 130A. Similarly, the hollow-head section 124B may slide along the second direction 20 upon expansion of the compressible matter 120B to inject the portion of the cool fluid 120A from the first volume portion 130A into the closed fluid loop 110. The functioning of the accumulator 106 is discussed in greater detail below.

Even though the CDU depicted in the example of FIG. 1A has a single accumulator connected to the closed fluid loop, in some other examples, the CDU may include a plurality of accumulators without deviating from the scope of the present disclosure. In some examples, the single accumulator may be too large to retrofit in an available space of the CDU due to one of a stroke length of the hollow piston, a diameter of the cylinder, or a combination thereof. Thus, the plurality of small-sized accumulators may be retrofitted in the available space of the CDU instead of the single accumulator to overcome the aforementioned problems related to the available space of the CDU. In such examples, an overall internal volume of the plurality of small-sized accumulators may need to match the internal volume of the single accumulator. In some examples, the plurality of small-sized accumulators may be connected to the closed fluid loop in one of a series configuration, a parallel configuration, or combinations thereof depending on the cooling requirement of the plurality of electronic systems.

Referring to FIG. 1A, the circulation pump 114 is a fluid pump. The pump-inlet 114A receives the cool fluid 120A directed from the heat exchanger 116 via the accumulator 106. The circulation pump 114 pumps the cool fluid 120A from the pump-inlet 114A to the plurality of electronic systems 102 via the cool fluid flow path 118A. In such examples, the cool fluid flow path 118A may be further connected to cooling conduits (not shown) disposed within the chassis 108 in either a series configuration or a parallel configuration. The cooling conduits may direct the flow of the cool fluid 120A to the cooling components, such as cold plates that are disposed in thermal contact with electronic components of each electronic system 102 to transfer the waste-heat from a respective electronic component to the cool fluid 120A, and thereby generate the hot fluid 120C. The cooling conduits may later direct the hot fluid 120C from the plurality of electronic systems 102 to the hot fluid flow path 118B.

The hot fluid flow path 118B may direct the flow of the hot fluid 120C from the plurality of electronic systems 102 into the heat exchanger 116. In one or more examples, the heat exchanger 116 dissipates the waste-heat in the hot fluid 120C and regenerates the cool fluid 120A. In some examples, the heat exchanger 116 may be a liquid heat-exchanger, a rear door heat-exchanger, or the like. In one or more examples, the heat exchanger 116 may receive facility cool fluid 142A from the data center environment 100 to dissipate the waste-heat from the hot fluid 120C and regenerate the cool fluid 120A. For example, the heat exchanger 116 may indirectly transfer the waste-heat from the hot fluid 120C to the facility cool fluid 142A, and regenerate the cool fluid 120A and a facility hot fluid 142B. The heat exchanger 116 may later direct the regenerated cool fluid 120A to the pump-inlet 114A of the circulation pump 114 via the accumulator 106.

The cool fluid reservoir assembly 112 may include a cool fluid reservoir 112A containing an add-in cool fluid 120D, add-in fluid pump 112B, and a connector fluid flow path 112C. For example, the cool fluid reservoir 112A is connected to the cool fluid flow path 118A via the connector fluid flow path 112C. Further, the add-in fluid pump 112B is connected to the connector fluid flow path 112C and configured to pump the add-in cool fluid 120D from the cool fluid reservoir 112A into the cool fluid flow path 118A. The cool fluid reservoir assembly 112 may function as a makeup reservoir for regulating loss of the cool fluid 120A in the closed fluid loop 110. For example, the CDU 104A may tend to lose some portion of cool fluid 120A over time due to evaporation within the closed fluid loop 110 and/or dripping from one or more plumbing joints of the CDU 104A. Accordingly, such loss of the cool fluid 120A may gradually decrease the operating pressure of the cool fluid 120A in the closed fluid loop 110. In such examples, when the operating pressure drops below a threshold pressure, the add-in fluid pump 112B may pump a portion of the add-in cool fluid 120D from the cool fluid reservoir 112A into the closed fluid loop 110 to return pressure levels to the operating pressure.

During the operation of the data center environment 100, the plurality of electronic systems 102 may generate a nominal amount of waste-heat while executing the one or more workloads. Accordingly, the cool fluid 120A directed in the closed fluid loop 110 and the compressible matter 120B filled in the second volume portion 130B may be maintained at the operating pressure while handling such nominal amount of the waste-heat, as shown in FIG. 1B. However, at times, the plurality of electronic systems 102 may generate either excessive amount or moderate amount of waste-heat due to varied power consumption rates while executing the one or more workloads. Accordingly, the operating pressure of the cool fluid 120A in the closed fluid loop 110 may fluctuate while handling such excessive or moderate amount of waste-heat, thus resulting in either expanding or contracting the compressible matter 120B in the second volume portion 130B so as to return the pressure levels of the cool fluid 120A in the closed fluid loop 110 to the operating pressure, as shown in FIGS. 10-1D.

For example, referring to FIG. 10, the excessive amount of the waste-heat may cause pressure spikes and/or a thermal expansion of the cool fluid 120A, resulting in an increase of the operating pressure of the cool fluid 120A in the closed fluid loop 110. In such examples, the compressible fluid 120B₁ may be contracted (or compressed) by the sliding movement of the hollow-head section 124B along the first direction 10 to allow extraction of a portion of the cool fluid 120A from the closed fluid loop 110 into the first volume portion 130A, thus allowing the pressure levels of the cool fluid 120A in the closed fluid loop 110 to return to the operating pressure. Accordingly, the accumulator 106 may move from the normal condition (or expanded condition) to the contracted condition to accommodate (or regulate) the increase in the operating pressure of the cool fluid 120A in the closed fluid loop 110. In some examples, when the accumulator 106 is in the contracted state, the compressible fluid 120B₁ may be compressed up to 10 percent of the internal volume 130 of the cylinder 122 to regulate the increase in the operating pressure of the cool fluid 120A in the closed fluid loop 110, for example, at the pump-inlet 114A of the circulation pump 114. Thus, the accumulator 106 may return the pressure levels of the cool fluid 120A in the closed fluid loop 110 to the operating pressure and prevent the problems associated with cavitation in the circulation pump 114 and in plumbing of the CDU 104A.

Similarly, referring to FIG. 1D, the moderate amount of the waste-heat may cause a thermal contraction of the cool fluid 120A, resulting in a decrease of the operating pressure of the cool fluid 120A in the closed fluid loop 110. In such examples, the compressible fluid 120B₁ may be expanded resulting in sliding the hollow-head section 124B along the second direction 20 and injecting the portion of the cool fluid 120A from the first volume portion 130A into the closed fluid loop 110, thus allowing the pressure levels of the cool fluid 120A in the closed fluid loop 110 to return to the operating pressure. Accordingly, the accumulator 106 may move to the expanded condition from the contracted condition (or normal condition) to accommodate (or regulate) the decrease in the operating pressure of the cool fluid 120A in the closed fluid loop 110. In some examples, when the accumulator 106 is in the expanded state, the compressible fluid 120B₁ may be expanded up to 90 percent of the internal volume 130 of the cylinder 122 to regulate the decrease in the operating pressure of the cool fluid 120A in the closed fluid loop 110, for example, at the pump-inlet 114A of the circulation pump 114. Thus, the accumulator 106 may return the pressure levels of the cool fluid 120A in the closed fluid loop 110 to the operating pressure and prevent the problems associated with cavitation in the circulation pump 114 and in plumbing of the CDU 104A.

In some examples, when the plurality of electronic systems 102 returns to generate the nominal amount of waste-heat, the cool fluid 120A may also return from the thermally expanded state or contracted state to a regular state in the closed fluid loop 110. In such examples, when the cool fluid 120A returns from the expanded state to the regular state in the closed fluid loop 110, the compressible matter 120B may expand to return the accumulator 106 back to the normal condition from the contracted condition. Accordingly, the accumulator 106 may inject the portion of the cool fluid 120A back into the closed fluid loop 110 from the first volume portion 130A and return the pressure levels of the cool fluid 120A to the operating pressure in the closed fluid loop 110. Similarly, when the cool fluid 120A returns from the contracted state to the regular state in the closed fluid loop 110, the compressible matter 120B may contract to return the accumulator 106 back to the normal condition from the expanded condition. Accordingly, the accumulator 106 may extract the portion of the cool fluid 120A back into the first volume portion 130A from the closed fluid loop 110, and return the pressure levels of the cool fluid 120A to the operating pressure in the closed fluid loop 110.

FIG. 2 depicts a cross-sectional view of an accumulator 206. As noted in the example of FIGS. 1A-1D, the accumulator 206 of FIG. 2 includes a cylinder 222 and a hollow piston 224. The cylinder includes an inlet 226, an outlet 228, and an internal volume 230 defined between the inlet 226 and the outlet 228. The hollow piston 224 includes a hollow-rod section 224A and a hollow-head section 224B extended from the hollow-rod section 224A. The hollow piston 224 is slidably connected to the cylinder 222 to split the internal volume 230 into a first volume portion 230A that is filled with the cool fluid 220A and a second volume portion 230B that is filled with a compressible matter 220B. The hollow-rod section 224A is connected to a flexible hose 232 and the outlet 228 of the cylinder 222 is connected to the rigid hose 234.

In the example of FIG. 2, the compressible matter 220B is a spring 220B₁, for example, a helical spring. In such examples, the spring 220B₁ has a first end 220B_{1A}, contacting the inlet 226 directly, a second end 220B_{1B} contacting the hollow-head section 224B, and a body section 220B_{1c} disposed around the hollow-rod section 224A. During the operation of a CDU, the hollow piston 224 reciprocates inside the cylinder 222 upon i) expansion of the spring 220B₁ to inject a portion of the cool fluid 220A from the first volume portion 230A into a closed fluid loop 210 and ii) contraction of the spring 220B₁ to extract the portion of the cool fluid 220A from the closed fluid loop 210 into the first volume portion 230A to regulate variations in the operating pressure of the cool fluid 220A in the closed fluid loop 210. Accordingly, the accumulator 206 may return the pressure levels of the cool fluid 220A in the closed fluid loop 210 to the operating pressure and prevent the problems associated with cavitation in a circulation pump and in plumbing of the CDU.

FIG. 3 depicts a cross-sectional view of an accumulator 306. As noted in the example of FIGS. 1A-1D, the accumulator 306 of FIG. 3 includes a cylinder 322 and a hollow piston 324. The cylinder includes an inlet 326, an outlet 328, and an internal volume 330 defined between the inlet 326 and the outlet 328. The hollow piston 324 includes a hollow-rod section 324A and a hollow-head section 324B extended from the hollow-rod section 324A. The hollow piston 324 is slidably connected to the cylinder 322 to split the internal volume 330 into a first volume portion 330A that is filled with the cool fluid 320A and a second volume portion 330B that is filled with a compressible matter 320B. The example of FIG. 3 additionally includes a hollow tube 376, which is disposed within the cylinder 322 and connected to the inlet 326 of the cylinder 322. The hollow tube 376 is further connected to a closed fluid loop 310 via a first hose 332. In such examples, an end section 324A₁ of the hollow-rod section 324A is disposed inside the hollow tube 376 and fluidically connected to the closed fluid loop 310 via the hollow tube 376. Further, a portion 324A₂ of the hollow-rod section 324A slides lengthwise relative to the hollow tube 376 when the hollow-head section 324B reciprocates inside the cylinder 322, as discussed in the example of FIGS. 1A-1D. Further, the outlet 328 of the cylinder 322 is connected to the closed fluid loop 310 via a second hose 334. In some examples, the first hose 332 and the second hose 334 are rigid hoses. In the example of FIG. 3, the compressible matter 320B is a compressible fluid 320B₁, such as air. During the operation of a CDU, the hollow piston 324 reciprocates inside the cylinder 322 upon i) expansion of the compressible fluid 320B₁ to inject a portion of the cool fluid 320A from the first volume portion 330A into a closed fluid loop 310 and ii) contraction of the compressible fluid 320B₁ to extract the portion of the cool fluid 320A from the closed fluid loop 310 into the first volume portion 330A to regulate variations in the operating pressure of the cool fluid 320A in the closed fluid loop 310. Accordingly, the accumulator 306 may return the pressure levels of the cool fluid 320A in the closed fluid loop 310 to the operating pressure and prevent the problems associated with cavitation in a circulation pump and in plumbing of the CDU.

FIG. 4 depicts a cross-sectional view of an accumulator 406. As noted in the example of FIGS. 1A-1D, the accumulator 406 of FIG. 4 includes a cylinder 422 and a hollow piston 424. The cylinder includes an inlet 426, an outlet 428, and an internal volume 430 defined between the inlet 426 and the outlet 428. The hollow piston 424 includes a hollow-rod section 424A and a hollow-head section 424B extended from the hollow-rod section 424A. The hollow piston 424 is slidably connected to the cylinder 422 to split the internal volume 430 into a first volume portion 430A that is filled with the cool fluid 420A and a second volume portion 430B that is filled with a compressible matter 420B. In the example of FIG. 4, the compressible matter 420B is a spring 420B₁, for example, a helical spring. In such examples, the spring 420B₁ has a first end 420B_{1A} contacting the inlet 426 via an intermediate end portion 427 of the cylinder 422, a second end 420B_{1B} contacting the hollow-head section 424B, and a body section 420B_{1c} disposed around the hollow-rod section 424A. The example of FIG. 4 additionally includes a hollow tube 476, which is disposed inside the cylinder 422 and connected to the inlet 426 of the cylinder 422. The hollow tube 476 is further connected to a closed fluid loop 410 via a first hose 432. In such examples, an end section 424A₁ of the hollow-rod section 424A is disposed inside the hollow tube 476 and fluidically connected to the closed fluid loop 410 via the hollow tube 476. Further, a portion 424A₂ of the hollow-rod section 424A slides lengthwise relative to the hollow tube 476 when the hollow-head section 424B reciprocates inside the cylinder 422, as discussed in the example of FIGS. 1A-1D. Further, the outlet 428 of the cylinder 422 is connected to the closed fluid loop 410 via a second hose 434. In some examples, the first hose 432 and the second hose 434 are rigid hoses. During the operation of a CDU, the hollow piston 424 reciprocates inside the cylinder 422 upon i) expansion of the spring 420B₁ to inject a portion of the cool fluid 420A from the first volume portion 430A into a closed fluid loop 410 and ii) contraction of the spring 420B₁ to extract the portion of the cool fluid 420A from the closed fluid loop 410 into the first volume portion 430A to regulate variations in the operating pressure of the cool fluid 420A in the closed fluid loop 410. Accordingly, the accumulator 406 may return the pressure levels of the cool fluid 420A in the closed fluid loop 410 to the operating pressure and prevent the problems associated with cavitation in a circulation pump and in plumbing of the CDU.

FIG. 5A depicts a cross-sectional view of an accumulator 506 in a contracted condition. FIG. 5B depicts a cross-sectional view of the accumulator 506 of FIG. 5A in an expanded condition. In the description hereinafter, FIGS. 5A-5B are described concurrently for ease of illustration.

As noted in the example of FIGS. 1A-1D, the accumulator 506 of FIG. 5 includes a cylinder 522 and a hollow piston 524. The cylinder 522 has an inlet 526, an outlet 528, and an internal volume 530 defined between the inlet 526 and the outlet 528. The hollow piston 524 has a hollow-rod section 524A and a hollow-head section 524B. The hollow piston 524 is slidably connected to the cylinder 522 via the outlet 528, unlike a hollow piston 124, which is slidably connected to the cylinder 122 via an inlet 126 as shown in the example of FIG. 1B. The hollow piston 524 slidably connected to the cylinder 522 splits the internal volume 530 into a first volume portion 530A and a second volume portion 530B. The first volume portion 530A is filled with a cool fluid 520A and the second volume portion 530B is filled with a compressible matter 520B, such as a compressible fluid. The first volume portion 530A is fluidically connected to a closed fluid loop 510 via the hollow piston 524 and the outlet 528 to allow a continuous flow of the cool fluid 520A into the closed fluid loop 510. Since the cool fluid 520A filled in the first volume portion 530A flows continuously, stagnation of the cool fluid 520A may not occur in the accumulator 506. Accordingly, the accumulator 506 of the present disclosure may overcome one or more problems associated with the stagnation of the cool fluid 520A stored in the existing accumulator.

Referring to FIG. 5B, when an operating pressure of the cool fluid 520A fluctuates, the accumulator 506 may either inject a portion of the cool fluid 520A into the closed fluid loop 508 from the first volume portion 530A to return the pressure levels to the operating pressure and/or extract the portion of the cool fluid 520A from the closed fluid loop 510 into the first volume portion 530A to return the pressure levels to the operating pressure. For example, the compressible matter 520B expands in the second volume portion 530B to slidably drive the hollow piston 524 and reduce the first volume portion 530A, thereby injecting the portion of the cool fluid 520A into the closed fluid loop 510. In such examples, the hollow-rod section 524A slides relative to the outlet 528 when the hollow-head section 524B is slidably driven by the expansion of the compressible matter 520B. Similarly, the compressible matter 520B is contracted in the second volume portion 530B by the sliding movement of the hollow piston 524 to allow extraction of the portion of the cool fluid 520A from the closed fluid loop 510 into the first volume portion 530A. Accordingly, the accumulator 506 may return the pressure levels of the cool fluid 520A in the closed fluid loop 510 to the operating pressure and prevent the problems associated with cavitation in a circulation pump and in plumbing of the CDU.

FIG. 6 is a flow diagram a flowchart depicting a method 600 of operating a cool fluid reservoir for managing the loss of the cool fluid in a coolant distribution unit. It should be noted herein that the method 600 is described in conjunction with FIGS. 1A-1C, for example.

The method 600 starts at block 602 and continues to block 604. At block 604, the method 600 includes directing a flow of a cool fluid into a closed fluid loop of a CDU via an accumulator. In some examples, the cool fluid reservoir includes a cylinder having an internal volume defined between an inlet and an outlet, and a hollow piston slidably connected to the cylinder via one of the inlet or the outlet to split the internal volume into a first volume portion that is filled with the cool fluid and a second volume portion that is filled with a compressible matter. In such examples, the compressible matter is maintained at an operating pressure by the cool fluid filled in the first volume portion via the hollow piston, and the first volume portion is fluidically connected to the closed fluid loop functioning at the operating pressure via the hollow piston and other one of the inlet or the outlet to allow a continuous flow of the cool fluid to the closed fluid loop via the cool fluid reservoir. Since the cool fluid filled in the internal volume (i.e., first volume portion) of the cool fluid reservoir flows continuously, stagnation of the cool fluid may not occur in the cool fluid reservoir. Accordingly, the accumulator of the present disclosure may overcome one or more problems associated with the stagnation of the cool fluid stored in the existing accumulator. The method 600 continues to block 606.

At block 606, the method 600 includes reciprocating the hollow piston inside the cylinder upon i) contraction of the compressible matter to extract the portion of the cool fluid from the closed fluid loop into the first volume portion and ii) expansion of the compressible matter to inject a portion of the cool fluid from the first volume portion into the closed fluid loop to regulate variations in the operating pressure of the cool fluid in the closed fluid loop. In one or more examples, reciprocating the hollow piston inside the cylinder includes sliding the hollow piston along a first direction to extract the portion of the cool fluid from the closed fluid loop into the first volume portion to regulate an increase in the operating pressure of the cool fluid in the closed fluid loop. Additionally, reciprocating the hollow piston inside the cylinder further includes sliding the hollow piston along a second direction opposite to the first direction to inject the portion of the cool fluid from the first volume portion into the closed fluid loop to regulate a decrease in the operating pressure of the cool fluid in the closed fluid loop. Since the compressible matter expands and contracts to reciprocate the hollow piston inside the cylinder to inject and extract the portion of the cool fluid into the closed fluid loop and the first volume portion respectively, the accumulator may regulate the pressure variations in the closed fluid loop. Accordingly, the accumulator may prevent the problems associated with the cavitation in circulation pumps and in plumbing of a CDU. In some examples, the cool fluid is one of a mixture of water and propylene glycol with additives, a dielectric fluid, water, or 460-CCL100, the compressible matter is one of a compressible spring or a compressible fluid, and the operating pressure is a range from about 10 pounds per square inch (psi) to 150 psi. The method 600 ends at block 608.

Various features as illustrated in the examples described herein may be implemented in an accumulator of a CDU, such as a centralized CDU or a rack-level or cabinet-level CDU. Accordingly, the accumulator may ensure that there is no stagnation of the cool fluid in its internal volume, and simultaneously manage variations in operating pressure of a cool fluid at a pump-inlet of a circulation pump. Since there is no stagnation of the cool fluid, the accumulator may reduce the risk of biological growth/contamination due to the stagnant fluid.

In the foregoing description, numerous details are set forth to provide an understanding of the subject matter disclosed herein. However, the implementation may be practiced without some or all of these details. Other implementations may include modifications, combinations, and variations from the details discussed above. It is intended that the following claims cover such modifications and variations.

What is claimed is:

1. An accumulator of a coolant distribution unit (CDU), comprising:
a cylinder having an internal volume defined between an inlet and an outlet; and
a hollow piston slidably connected to the cylinder through one of the inlet or the outlet to split the internal volume into a first volume portion that is filled with a cool fluid and a second volume portion that is filled with a compressible matter,
wherein the compressible matter is maintained at an operating pressure by the cool fluid filled in the first volume portion via the hollow piston, and wherein the first volume portion is fluidically connected to a closed fluid loop functioning at the operating pressure via the hollow piston and other one of the inlet or the outlet to direct a flow of the cool fluid into the closed fluid loop via the accumulator.

2. The accumulator of claim 1, wherein the hollow piston reciprocates inside the cylinder upon i) contraction of the compressible matter to extract a portion of the cool fluid from the closed fluid loop into the first volume portion and ii) expansion of the compressible matter to inject the portion of the cool fluid from the first volume portion into the closed fluid loop to regulate variations in the operating pressure of the cool fluid in the closed fluid loop.

3. The accumulator of claim 2, wherein reciprocating the hollow piston inside the cylinder comprises sliding the hollow piston along a first direction to extract the portion of the cool fluid from the closed fluid loop into the first volume portion to regulate an increase in the operating pressure of the cool fluid in the closed fluid loop.

4. The accumulator of claim 3, wherein reciprocating the hollow piston inside the cylinder further comprises sliding the hollow piston along a second direction opposite to the first direction to inject the portion of the cool fluid from the first volume portion into the closed fluid loop to regulate a decrease in the operating pressure of the cool fluid in the closed fluid loop.

5. The accumulator of claim 1, wherein the cool fluid is one of a mixture of water and propylene glycol with additives, a dielectric fluid, water, or a 460-CCL100 fluid, and wherein the operating pressure is in a range from about 10 pounds per square inch (psi) to 150 psi.

6. The accumulator of claim 1, wherein the compressible matter is a compressible spring having a first end contacting the one of the inlet or the outlet and a second end contacting the hollow piston.

7. The accumulator of claim 1, wherein the compressible matter is a compressible fluid filled within the second volume portion.

8. The accumulator of claim 7, further comprising a pair of first sealing elements coupled to the one of the inlet or the outlet and a pair of second sealing elements coupled to a hollow-head section of the hollow piston, wherein the pair of first sealing elements seals a first contact interface between a hollow-rod section of the hollow piston and the one of the inlet or the outlet to prevent leakage of the compressible fluid outside the second volume portion, and wherein the pair of second sealing elements seals a second contact interface between the hollow-head section and an inner surface of the cylinder to prevent the leakage of i) the compressible fluid from the second volume portion into the first volume portion and ii) the cool fluid from the first volume portion into the second volume portion.

9. The accumulator of claim 1, further comprising a hollow tube disposed within the cylinder and coupled to the other one of the inlet or the outlet, wherein a section of the hollow piston is disposed inside the hollow tube and fluidically connected to the closed fluid loop via the hollow tube, and wherein the section of the hollow piston slides along a first direction and a second direction relative to the hollow tube when the hollow piston reciprocates inside the cylinder.

10. A coolant distribution unit (CDU) comprising:
a closed fluid loop;
a circulation pump connected to the closed fluid loop for pumping a cool fluid into the closed fluid loop; and
an accumulator disposed in a fluid flow path defined by the closed fluid loop, comprising:
a cylinder having an internal volume defined between an inlet and an outlet; and
a hollow piston slidably connected to the cylinder through one of the inlet or the outlet to split the internal volume into a first volume portion that is filled with the cool fluid and a second volume portion that is filled with a compressible matter,
wherein the compressible matter is maintained at an operating pressure by the cool fluid filled in the first volume portion via the hollow piston, wherein the first volume portion is fluidically connected to the closed fluid loop functioning at the operating pressure via the hollow piston and other one of the inlet or the outlet to direct a flow of the cool fluid into the fluid flow path, and wherein the hollow piston reciprocates inside the cylinder upon i) contraction of the compressible matter to extract a portion of the cool fluid from the closed fluid loop into the first volume portion and ii) expansion of the compressible matter to inject the portion of the cool fluid from the first volume portion into the closed fluid loop to regulate variations in the operating pressure of the cool fluid at a pump-inlet of the circulation pump.

11. The CDU of claim 10, wherein reciprocating the hollow piston inside the cylinder comprises sliding the hollow piston along a first direction to extract the portion of the cool fluid from the closed fluid loop into the first volume portion to regulate an increase in the operating pressure of the cool fluid in the closed fluid loop.

12. The CDU of claim 11, wherein reciprocating the hollow piston inside the cylinder further comprises sliding the hollow piston along a second direction opposite to the first direction to inject the portion of the cool fluid from the first volume portion into the closed fluid loop to regulate a decrease in the operating pressure of the cool fluid in the closed fluid loop.

13. The CDU of claim 10, wherein the cool fluid is one of a mixture of water and propylene glycol with additives, a dielectric fluid, water, or a 460-CCL100 fluid, and wherein the operating pressure is a range from about 10 pounds per square inch (psi) to 150 psi.

14. The CDU of claim 10, wherein the compressible matter is a compressible spring having a first end contacting the one of the inlet or the outlet and a second end contacting the hollow piston.

15. The CDU of claim 10, wherein the compressible matter is a compressible fluid filled within the second volume portion.

16. The CDU of claim 15, wherein the accumulator further comprises a pair of first sealing elements coupled to the one of the inlet or the outlet and a pair of second sealing elements coupled to a hollow-head section of the hollow piston, wherein the pair of first sealing elements seals a first contact interface between a hollow-rod section of the hollow piston and the one of the inlet or the outlet to prevent leakage of the compressible fluid outside the second volume portion, and wherein the pair of second sealing elements seals a second contact interface between the hollow-head section and an inner surface of the cylinder to prevent the leakage of i) the compressible fluid from the second volume portion into the first volume portion and ii) the cool fluid from the first volume portion into the second volume portion.

17. The CDU of claim 10, wherein the accumulator further comprises a hollow tube disposed within the cylinder and coupled to the other one of the inlet or the outlet, wherein a section of the hollow piston is disposed inside the hollow tube and fluidically connected to the closed fluid loop via the hollow tube, and wherein the section of the hollow piston slides along a first direction and a second direction relative to the hollow tube when the hollow piston reciprocates inside the cylinder.

18. A method comprising:
directing a flow of a cool fluid into a closed fluid loop of a coolant distribution unit (CDU) via an accumulator comprising a cylinder having an internal volume defined between an inlet and an outlet, and a hollow piston slidably connected to the cylinder via one of the inlet or the outlet to split the internal volume into a first volume portion that is filled with the cool fluid and a second volume portion that is filled with a compressible matter,
wherein the compressible matter is maintained at an operating pressure by the cool fluid filled in the first volume portion via the hollow piston and wherein the first volume portion is fluidically connected to the closed fluid loop functioning at the operating pressure via the hollow piston and other one of the inlet or the outlet; and
reciprocating the hollow piston inside the cylinder upon i) contraction of the compressible matter to extract a portion of the cool fluid from the closed fluid loop into the first volume portion and ii) expansion of the compressible matter to inject the portion of the cool fluid from the first volume portion into the closed fluid loop to regulate variations in the operating pressure of the cool fluid in the closed fluid loop.

19. The method of claim 18, wherein reciprocating the hollow piston inside the cylinder comprises:
sliding the hollow piston along a first direction to extract the portion of the cool fluid from the closed fluid loop into the first volume portion to regulate an increase in the operating pressure of the cool fluid in the closed fluid loop; and
sliding the hollow piston along a second direction opposite to the first direction to inject the portion of the cool fluid from the first volume portion into the closed fluid loop to regulate a decrease in the operating pressure of the cool fluid in the closed fluid loop.

20. The method of claim 18, wherein the cool fluid is one of a mixture of water and propylene glycol with additives, a dielectric fluid, water, or a 460-CCL100 fluid, wherein the compressible matter is one of a compressible spring or a compressible fluid, and wherein the operating pressure is a range from about 10 pounds per square inch (psi) to 150 psi.
